(19) United States
(12) Patent Application Publication
(10) Pub. No.: US 2009/0101948 A1
(43) Pub. Date: Apr. 23, 2009

(54) CMOS image sensors having transparent transistors and methods of manufacturing the same

(75) Inventors: Young-soo Park, Yongin-si (KR); Seung-hyuk Chang, Seongnam-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/078,404

(22) Filed: Mar. 31, 2008

(30) Foreign Application Priority Data
Oct. 19, 2007 (KR) 10-2007-0105791

(51) Int. Cl. H01L 31/00

(52) U.S. Cl. 257/292; 257/E31.001

(57) ABSTRACT

CMOS image sensors having transparent transistors and methods of manufacturing the same are provided. The CMOS image sensors include a photodiode and at least one transistor formed on the photodiode. The image sensor may include a plurality of transistors wherein at least one of the plurality of transistors is a transparent transistor.

### PRIORITY STATEMENT

This application claims the benefit of priority under 35 U.S.C. §119 from Korean Patent Application No. 10-2007-0105791, filed on Oct. 19, 2007, in the Korean Intellectual Property Office, the disclosure of which is incorporated herein in its entirety by reference.

### BACKGROUND

1. Field

Example embodiments relate to complementary metal oxide semiconductor (CMOS) image sensors having a larger photodiode region by forming transparent transistors on the photodiode and methods of manufacturing the same.

2. Description of the Related Art

An image sensor is a photoelectric transducer that converts light into an electric signal. A conventional image sensor includes a plurality of unit pixels arranged in an array on a semiconductor substrate. Each of the unit pixels includes a photodiode and a plurality of transistors. The photodiode generates and stores photocharges by detecting light from the outside. The transistors output electrical signals according to an amount of the photocharges.

A complementary metal oxide semiconductor (CMOS) image sensor includes a photodiode that receives and stores an optical signal. The CMOS image sensor displays an image via a control device that controls or processes the optical signal. The control device may be manufactured using a CMOS manufacturing technique. The CMOS image sensor may be manufactured, in one chip, with various signal processing devices.

In the CMOS device, because the photodiode and the plurality of transistors are integrated in one chip, a region for the photodiode is limited. Color filters for selecting a specific wavelength may be formed on the photodiode region. As the photodiode region is reduced, a dynamic range of CMOS image sensor may be reduced, decreasing the sensitivity of the image sensor.

### SUMMARY

Example embodiments provide complementary metal oxide semiconductor (CMOS) image sensors having a larger photodiode region using transparent transistors and methods of manufacturing the same.

Example embodiments relate to CMOS image sensors having a larger photodiode region by forming transparent transistors on the photodiode and methods of manufacturing the same.

According to example embodiments, there are provided CMOS image sensors including a photodiode and at least one transistor formed on the photodiode.

The image sensor may include a plurality of transistors. The at least one transistor may be a transparent transistor. The transistor may include a channel layer formed of a semiconductor oxide.

The semiconductor oxide may be at least one selected from the group consisting of ZnO, SnO, InO and combinations thereof. The semiconductor oxide may include at least one selected from the group consisting of Ta, Hf, In, Ga, Sr alloys and combinations thereof.

The at least one transistor may include a source electrode and a drain electrode on a first insulating layer that covers the photodiode, a semiconductor oxide layer formed of the semiconductor oxide and covering the source electrode and the drain electrode on the first insulating layer, a second insulating layer covering the oxide semiconductor layer, and a gate electrode formed between the source electrode and the drain electrode on the second insulating layer.

The source and drain electrodes may be transparent electrodes. The transparent electrodes may be formed of indium tin oxide (ITO).

According to other example embodiments, there are provided methods of manufacturing a CMOS image sensor including forming at least one transistor on a photodiode.

The transistor may be a transparent transistor. The transparent electrode may be formed of indium tin oxide (ITO). The methods may include forming a plurality of transistors.

Forming the at least one transistor may include forming a channel layer of a semiconductor oxide. The semiconductor oxide may be at least one selected from the group consisting of zinc oxide (ZnO), tin oxide (SnO), indium oxide (InO) and combinations thereof. The semiconductor oxide may include at least one selected from the group consisting of tantalum (Ta), hafnium (Hf), indium (In), gallium (Ga), strontium (Sr) and combinations thereof.

Forming the at least one transistor may include forming a source electrode and a drain electrode on a first insulating layer that covers the photodiode, forming an semiconductor oxide layer covering the source electrode and the drain electrode, forming a second insulating layer covering the semiconductor oxide layer, and forming a gate electrode on the second insulating layer between the source electrode and the drain electrode.

### BRIEF DESCRIPTION OF THE DRAWINGS

Example embodiments will be more clearly understood from the following detailed description taken in conjunction with the accompanying drawings. FIGS. 1-7 represent non-limiting, example embodiments as described herein.

FIG. 1 is a diagram illustrating a plan view of a complementary metal oxide semiconductor (CMOS) image sensor according to example embodiments;

FIG. 2 is a diagram illustrating a cross-sectional view taken along line II-II of FIG. 1;

FIG. 3 is a diagram illustrating a cross-sectional view taken along line III-III of FIG. 1;

FIG. 4 is an equivalent circuit diagram of the image sensor depicted in FIGS. 1 through 3;

FIG. 5 is a diagram illustrating a plan view of a complementary metal oxide semiconductor (CMOS) image sensor according to example embodiments;

FIG. 6 is a diagram illustrating a cross-sectional view taken along line VI-VI of FIG. 5; and

FIG. 7 is an equivalent circuit diagram of the image sensor depicted in FIGS. 5 and 6.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

A complementary metal oxide semiconductor (CMOS) image sensor according to example embodiments will now be described more fully with reference to the accompanying drawings in which example embodiments are shown.

Although the example embodiments are described with respect to “transparent transistors,” non-transparent transistors may also be used. The term “transparent transistor” is used for differentiating the example embodiments from other inventions, and thus, should not be construed as being limited to the embodiments set forth herein.

A CMOS image sensor includes a plurality of pixels arranged two-dimensionally. Each of the pixels may include a light collecting lens for sending a substantial amount of light to a photodiode below the light collecting lens and a color filter that transmits a light having a specific wavelength and blocks light having a different wavelength to the photodiode. In the following description, only the unit pixel will be described, and the configuration of the light collecting lens and the color filter are omitted in the drawings.

Example embodiments relate to complementary CMOS image sensors having a larger photodiode region by forming transparent transistors on the photodiode and methods of manufacturing the same.

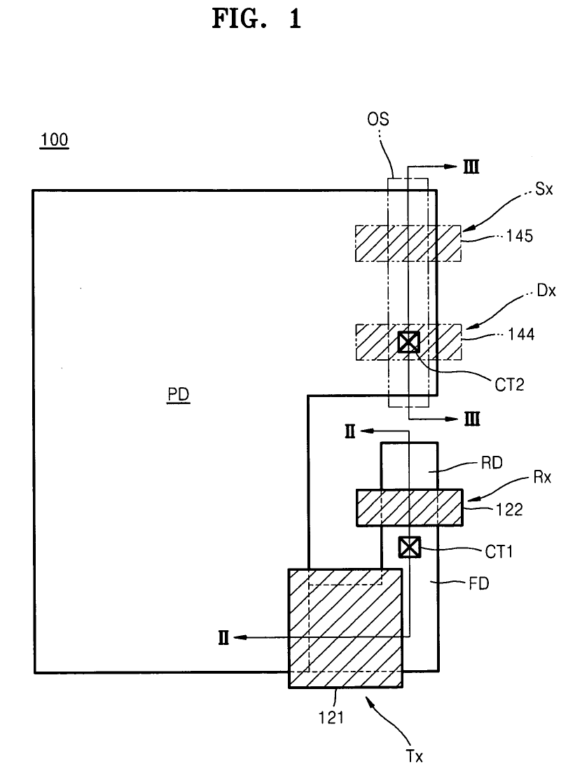

FIG. 1 is a diagram illustrating a plan view of a CMOS image sensor 100 having transparent transistors according to example embodiments.

Referring to FIG. 1, the CMOS image sensor 100 includes a photodiode PD and four gate electrodes. The four gate electrodes include a transfer gate 121, a reset gate 122, a drive gate 144, and a selection gate 145. The gate electrodes may be included in a transfer transistor Tx, a reset transistor Rx, a drive transistor Dx and a selection transistor Sx, respectively.

The transfer transistor Tx and the reset transistor Rx may be formed on a side of the photodiode PD. A semiconductor oxide layer OS may be formed on a portion of the photodiode PD. The drive transistor Dx and the selection transistor Sx may be formed on the semiconductor oxide layer OS.

The photodiode PD may be a region where electrons and holes are generated by light reaching the photodiode PD. In example embodiments, the region of the photodiode PD may be larger that in the conventional photodiode because the photodiode PD may be formed in the drive transistor Dx and the selection transistor Sx regions.

A first contact CT1 and a second contact CT2 may be electrically connected to each other through a wire (not shown).

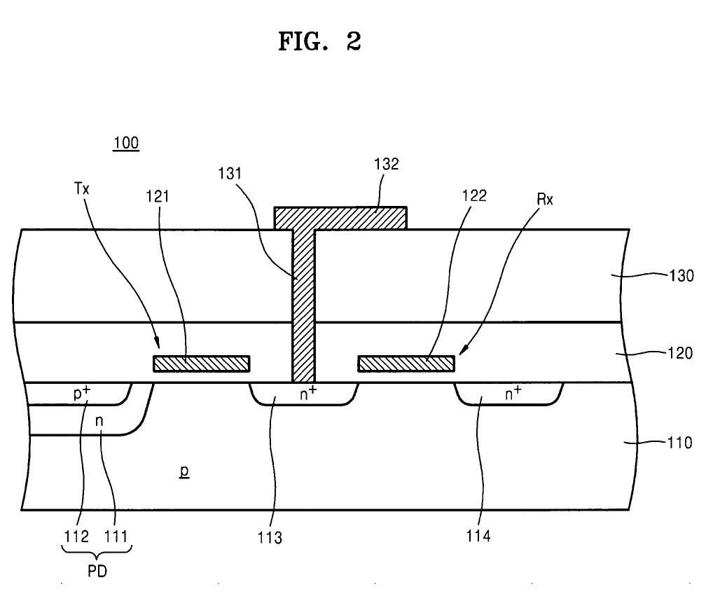

FIG. 2 is a diagram illustrating a cross-sectional view taken along line II-II of FIG. 1.

Referring to FIG. 2, an N-well region 111 may be formed in a semiconductor substrate 110 (e.g., a p-type Si substrate). A p-type impurity region 112 may be formed on a surface of the N-well region 111. The N-well region 111 and the p-type impurity region 112 form the photodiode PD.

A floating diffusion region 113 and a reset diffusion region 114, which are doped with an n-type impurity, may be formed on a side of the photodiode PD. The floating diffusion region 113 and the reset diffusion region 114 may be doped such that the regions 113 and 114 have a potential lower than that of the photodiode PD. The floating diffusion region 113 and the reset diffusion region 114 are depicted as FD and RD, respectively, in FIG. 1.

A first insulating layer 120 may be formed on the substrate 110. A transfer gate 121 may be formed between the N-well region 111 and the floating diffusion region 113. A reset gate 122 may be formed between the floating diffusion region 113 and the reset diffusion region 114 in the first insulating layer 120. The N-well region 111 of the photodiode PD, the floating diffusion region 113 and the transfer gate 121 form a transfer transistor Tx. The floating diffusion region 113, the reset diffusion region 114 and the reset gate 122 form a reset transistor Rx.

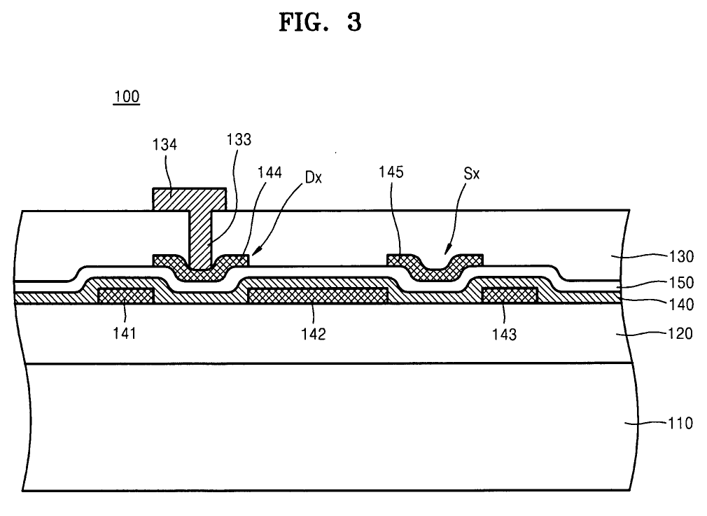

A second insulating layer 130 may be formed on the first insulating layer 120. The first insulating layer 120 and the second insulating layer 130 may be formed of a silicon oxide. A first contact 131 may be formed on the floating diffusion region 113 through the first insulating layer 120 and the second insulating layer 130. The first contact 131 may be connected via a wire 132 to a second contact 133, described below in FIG. 3, connected to a selection gate SG of a select transistor Sx.

FIG. 3 is a diagram illustrating a cross-sectional view taken along line III-III of FIG. 1.

Referring to FIG. 3, a source electrode 141, a common electrode 142, and a drain electrode 143 may be formed on the first insulating layer 120. A semiconductor oxide layer 140 covering the source electrode 141, the common electrode 142, and the drain electrode 143 and a third insulating layer 150 may be formed on the semiconductor oxide layer 140. The third insulating layer 150 may be formed of the same material as the first and second insulating layers 120 and 130.

A drive gate 144 may be formed on the third insulating layer 150 between the source electrode 141 and the common electrode 142. A selection gate 145 may be formed on the third insulating layer 150 between the common electrode 142 and the drain electrode 143. The source electrode 141, the common electrode 142 and the drive gate 144 form a drive transistor Dx. The common electrode 142, the drain electrode 143 and the selection gate 145 form a selection transistor Sx.

The second contact 133 may be formed on the drive gate 144. A wire 134 connected to the contact 133 may be connected to the wire 132 in FIG. 2.

The semiconductor oxide layer 140 forms a charge moving channel between the electrodes of the transistors. The semiconductor oxide layer 140 may be formed of a transparent material. The semiconductor oxide layer 140 may be formed of ZnO, SnO or InO and an oxide of ZnO, SnO or InO including Ta, Hf, In, Ga or Sr.

The source electrode 141, the common electrode 142, the drain electrode 143, the contacts 131 and 133 and the wires 132 and 134 may be formed of a transparent material (e.g., indium tin oxide (ITO)).

Although not shown in FIGS. 1 through 3, contacts and wires connected to gates TG, RG, and SG, and contacts and wires connected to the reset diffusion region RD and the drain electrode 143 may be formed of a transparent material (e.g., ITO).

In the CMOS image sensor 100 according to example embodiments, regions under the selection transistor Sx and the drive transistor Dx may be used as a photodiode region. The region of the photodiode PD may be increased by approximately 40% compared to forming the transistors on a side of a photodiode region. The increase in the photodiode region increases the capacity of accommodating electrons generated in the photodiode PD. As such, the dynamic range of the CMOS image sensor 100 may be increased.

The selection transistor Sx and the drive transistor Dx may be formed of a transparent material. A region where light is irradiated is enlarged, increasing the sensitivity of the CMOS image sensor 100.

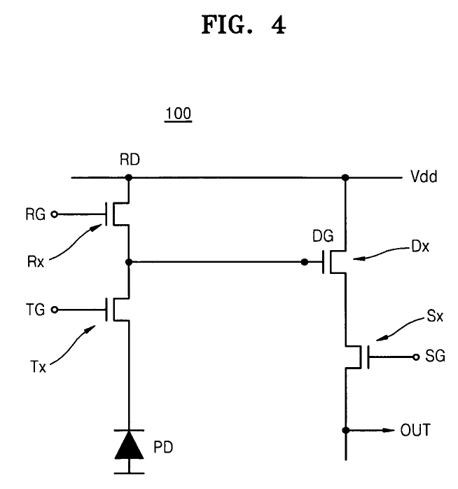

FIG. 4 is an equivalent circuit diagram of the CMOS image sensor 100 depicted in FIGS. 1 through 3.

Referring to FIG. 4, the CMOS image sensor includes the photodiode PD, the transfer transistor Tx, the reset transistor Rx, the drive transistor Dx and the selection transistor Sx.

The photodiode PD receives optical energy and generates charges in response to the optical energy. The transfer transistor Tx controls the transportation of generated charges to a floating diffusion region FD through a transfer gate TG. The reset transistor Rx resets a potential of the floating diffusion region FD by controlling an input power Vdd through a reset gate RG. The drive transistor Dx functions as a source follower amplifier. The selection transistor Sx is a switching device that selects a unit pixel through a selection gate SG. The floating diffusion region FD is connected to a drive gate DG and the potential of the floating diffusion region may be outputted through an output line OUT via a source follower circuit comprising FD the drive transistor Dx and the selection transistor Sx.

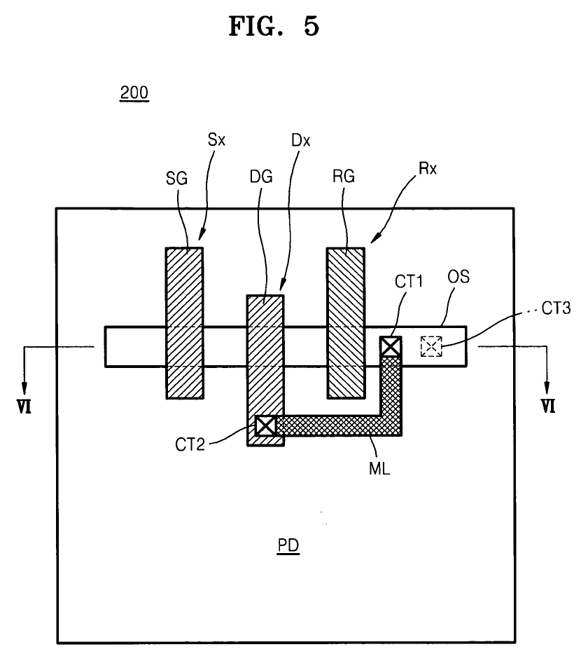

FIG. 5 is a diagram illustrating a plan view of a CMOS image sensor 200 having transparent transistors according to example embodiments.

The CMOS image sensor 200 includes a photodiode PD and three gates. The three gates include a reset gate 246, a drive gate 247 and a selection gate 248. The reset gate 246, the drive gate 247 and the selection gate 248 may be included in a reset transistor Rx, a drive transistor Dx and a selection transistor Sx, respectively.

A semiconductor oxide layer OS may be formed on the photodiode PD. Electrodes may be formed on the semiconductor oxide layer OS and the photodiode PD. The reset gate 246, the drive gate 247 and the selection gate 248 may be formed on the semiconductor oxide layer OS.

The photodiode PD may be a region where electrons and holes are generated by light reaching the photodiode PD. The photodiode PD may be formed under the reset transistor Rx, the drive transistor Dx and the selection transistor Sx. As such, the region of the photodiode PD may be expanded.

A first contact CT1 and a second contact CT2 may be electrically connected via a metal line ML. A third contact CT3 will be described later.

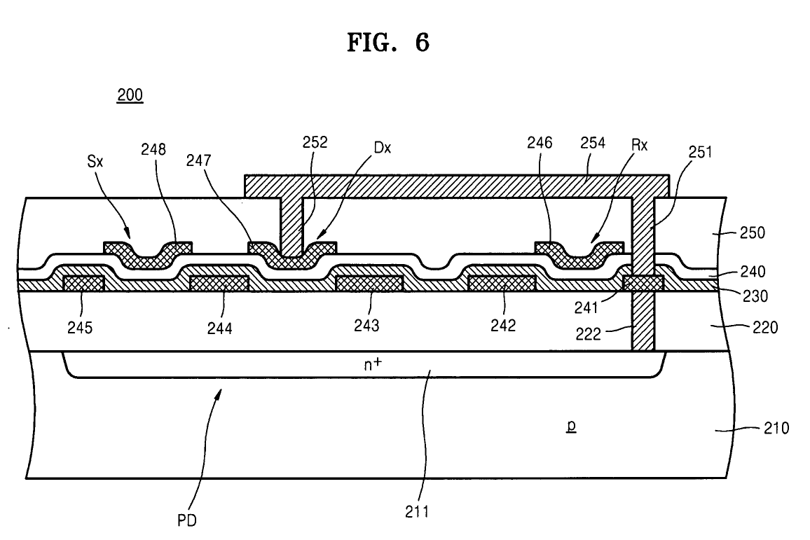

FIG. 6 is a diagram illustrating a cross-sectional view taken along line VI-VI—of FIG. 5.

Referring to FIG. 6, an N-well region 211 may be formed in a semiconductor substrate 210 (e.g., a p-type Si substrate). The N-well region 211 and the substrate 210 form the photodiode PD.

A first insulating layer 220 covering the photodiode PD may be formed on the p-type Si substrate 210. First, second, third, fourth and fifth electrodes 241, 242, 243, 244 and 245 may be formed on the first insulating layer 220. The first, second, third, fourth and fifth electrodes 241, 242, 243, 244 and 245 respectively may be a source electrode, a drain electrode, a source electrode, a common electrode and a drain electrode, respectively. A third contact 222 that connects the N-well region 211 to the first electrode 241 may be formed in the first insulating layer 220.

An semiconductor oxide layer 230 covering the first, second, third, fourth and fifth electrodes 241, 242, 243, 244 and 245 may be formed on the first insulating layer 220. A second insulating layer 240 may be formed on the semiconductor oxide layer 230. A reset gate 246 may be formed on the second insulating layer 240 between the first electrode 241 and the second electrode 242. A drive gate 247 may be formed on the second insulating layer 240 between the third and fourth electrodes 243 and 244. A selection gate 248 may be formed on the second insulating layer 240 between the fourth and fifth electrodes 244 and 245. The first electrode 241, second electrode 242 and the reset gate 246 form a reset transistor Rx. The third and fourth electrodes 243 and 244 and the drive gate 247 form a drive transistor Dx. The fourth and fifth electrodes 244 and 245 and the selection gate 248 form a selection transistor Sx.

A third insulating layer 250 may be formed on the second insulating layer 240. The first insulating layer 220, the second insulating layer 240 and the third insulating layer 250 may be formed of a silicon oxide. In other example embodiments, the first insulating layer 220, the second insulating layer 240 and third insulating layer 250 may be formed of insulating materials different from each other.

A first contact 251 that penetrates through the first insulating layer 220, the second insulating layer 240, and the third insulating layer 250 may be formed on the first electrode 241. A second contact 252 that penetrates through the third insulating layer 250 may be formed on the drive gate 247. The first contact 241 and the second contact 252 may be connected to each other through a metal line 254.

The semiconductor oxide layer 230 forms a charge transportation channel between the electrodes of the transistors. The semiconductor oxide layer 230 may be formed of a transparent material. The semiconductor oxide layer 230 may be formed of an oxide selected from the group consisting of ZnO, SnO, InO, or combinations thereof. The oxides (ZnO, SnO, InO) may include Ta, Hf, In, Ga, Sr or combinations thereof.

The first, second, third, fourth and fifth electrodes 241, 242, 243, 244 and 245, the contacts 222, 251 and 252, and the wire 254 may be formed of a transparent material (e.g., ITO).

Although not shown in FIGS. 5 and 6, contacts and wires connected to the reset and selection gates 246 and 248 and contacts and wires connected to the electrodes 242 and 243 may be formed of a transparent material (e.g., ITO).

In the CMOS image sensor 200 according to example embodiments, a region under the reset transistor Rx, the selection transistor Sx and the drive transistor Dx may be used as the photodiode region. As such, the region of the photodiode PD increases in comparison to transistors formed on a side of the photodiode region. The increase in the photodiode region increases the capacity of accommodating electrons generated in the photodiode PD, increasing the dynamic range of the CMOS image sensor.

Because the reset transistor Rx, the selection transistor Sx, and the drive transistor Dx are formed of a transparent material, a region where light is irradiated is increased, increasing the sensitivity of the CMOS image sensor.

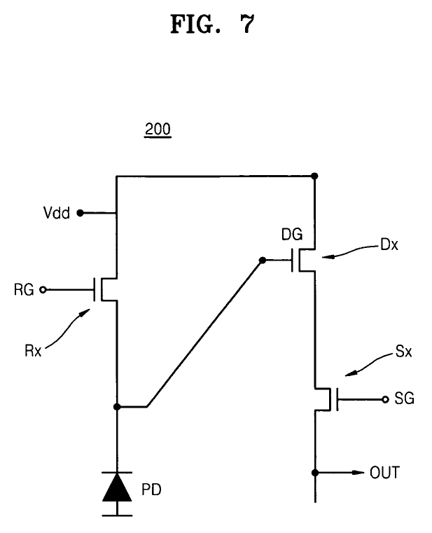

FIG. 7 is an equivalent circuit diagram of the image sensor shown in FIGS. 5 and 6.

Referring to FIG. 7, the CMOS image sensor 200 includes the photodiode PD, the reset transistor Rx, the drive transistor Dx and the selection transistor Sx.

The reset transistor Rx may reset a source potential of the reset transistor Rx to an input voltage Vdd by controlling the input voltage Vdd through a reset gate RG. The photodiode PD receives optical energy and generates charges in response to the optical energy. The charges generated from the photodiode PD may be moved to the outside. As such, the source potential of the reset transistor may decrease, changing a bias voltage of the drive gate DG connected to the reset transistor Rx. The changed bias voltage may be outputted through an output line OUT. The selection transistor Sx is a switching device that selects a unit pixel through the selection gate SG.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A CMOS image sensor, comprising:
a photodiode; and
at least one transistor on the photodiode.

2. The CMOS image sensor of claim 1, further comprising a plurality of transistors.

3. The CMOS image sensor of claim 1, wherein the at least one transistor is a transparent transistor.

4. The CMOS image sensor of claim 1, wherein the at least one transistor includes a channel layer formed of a semiconductor oxide.

5. The CMOS image sensor of claim 4, wherein the semiconductor oxide is at least one selected from the group consisting of zinc oxide (ZnO), tin oxide (SnO), indium oxide (InO) and combinations thereof.

6. The CMOS image sensor of claim 5, wherein the semiconductor oxide includes at least one selected from the group consisting of tantalum (Ta), hafnium (Hf), indium (In), gallium (Ga), strontium (Sr) and combinations thereof.

7. The CMOS image sensor of claim 1, wherein each of the at least one transistor includes a source electrode and a drain electrode on a first insulating layer that covers the photodiode, a semiconductor oxide layer covering the source electrode and the drain electrode on the first insulating layer, a second insulating layer covering the semiconductor oxide layer, and a gate electrode on the second insulating layer between the source electrode and the drain electrode.

8. The CMOS image sensor of claim 7, wherein the source and drain electrodes are transparent electrodes.

9. The CMOS image sensor of claim 8, wherein the transparent electrodes are formed of indium tin oxide (ITO).
